(19) United States
(12) Patent Application Publication
(10) Pub. No.: US 2021/0041782 A1
(43) Pub. Date: Feb. 11, 2021

(54) IMPRINT TEMPLATE AND METHOD FOR MANUFACTURING THE SAME

(71) Applicant: KIOXIA CORPORATION, Tokyo (JP)

(72) Inventors: Takeshi HIGUCHI, Yokohama Kanagawa (JP); Hirokazu KATO, Kariya Aichi (JP); Kasumi OKABE, Yokohama Kanagawa (JP)

(21) Appl. No.: 16/807,566

(22) Filed: Mar. 3, 2020

(30) Foreign Application Priority Data
Aug. 7, 2019 (JP) 2019-145704

(51) Int. Cl. G03F 7/00

(52) U.S. Cl. CPC G03F 7/0002

(57) ABSTRACT

An imprint template includes a substrate, a resin film, and a resist-repellant layer. The resin film is provided on the substrate and has an imprint pattern therein. The resist-repellant layer is provided on a surface of the imprint pattern. The resist-repellant layer includes an inorganic element. A method for manufacturing an imprint template includes pressing a substrate against a resin film that has been solidified in a mold having a pattern therein. The resin film having an imprint pattern corresponding to the pattern is thereby transferred to the substrate. A resist-repellant layer is then formed on a surface of the imprint pattern. The resist-repellant layer includes an inorganic element.

### CROSS-REFERENCE TO RELATED APPLICATION(S)

This application is based upon and claims the benefit of priority from Japanese Patent Application No. 2019-145704, filed on Aug. 7, 2019, the entire contents of which are incorporated herein by reference.

### FIELD

Embodiments described herein relate generally to an imprint template, a method for manufacturing the imprint template, a method for forming a pattern, and a method for manufacturing a semiconductor device.

### BACKGROUND

An imprinting method has been developed as a method for forming a fine pattern in manufacturing semiconductor devices. In the imprinting method, a resist is dispensed on a processing target film, and an imprint template with a pattern is pressed against the resist, whereby the pattern of the imprint template is transferred to the resist.

The imprint template is made of, for example, quartz, and is abraded by repeated use, and therefore, the imprint template has a relatively short service lifetime and is high in cost. It may be possible to reduce the cost of an imprint template by using a relatively inexpensive material for the imprint template. However, in this case, a resist may adhere to the imprint template.

### DESCRIPTION OF THE DRAWINGS

FIGS. 1A and 1B illustrate a structure of an imprint template according to an embodiment, in which FIG. 1A is a cross-sectional view and FIG. 1B is a plan view.

FIGS. 2A to 2C illustrate a flow of an example of a procedure of a method for manufacturing the imprint template according to the embodiment.

FIGS. 3A and 3B illustrate a flow of an example of the procedure of the method for manufacturing the template according to the embodiment.

FIG. 4 illustrates an example of a configuration of an imprinting apparatus according to the embodiment.

FIGS. 5A to 5E illustrate a flow of an example of a procedure of an imprinting method using the imprint template according to the embodiment.

FIGS. 6A and 6B illustrate a flow of an example of a procedure of a method for manufacturing an imprint template of a modification example according to the embodiment.

### DETAILED DESCRIPTION

Embodiments provide an imprint template that is not susceptible to adhesion of a resist, a method for manufacturing the imprint template, a method for forming a pattern, and a method for manufacturing a semiconductor device.

In general, according to an embodiment, an imprint template includes a substrate, a resin film, and a resist-repellant layer. The resin film is on the substrate and having an imprint pattern. The resist-repellant layer is on a surface of the imprint template pattern. The resist-repellant layer includes an inorganic element.

According to an embodiment, a method for manufacturing an imprint template includes pressing a substrate against a resin film that is solidified in a mold having a pattern, thereby transferring the resin film having an imprint template pattern corresponding to the pattern onto the substrate, and forming a resist-repellant layer on a surface of the imprint template pattern. The resist-repellant layer includes an inorganic element.

Hereinafter, exemplary embodiments of the present disclosure will be described with reference to the drawings. The example embodiments are not intended to limit the present disclosure. The following embodiments may include additional elements or modifications that are easily conceivable by a person of ordinary skill in the art and such additional elements or modifications are within the scope of the present disclosure.

Structure of Template

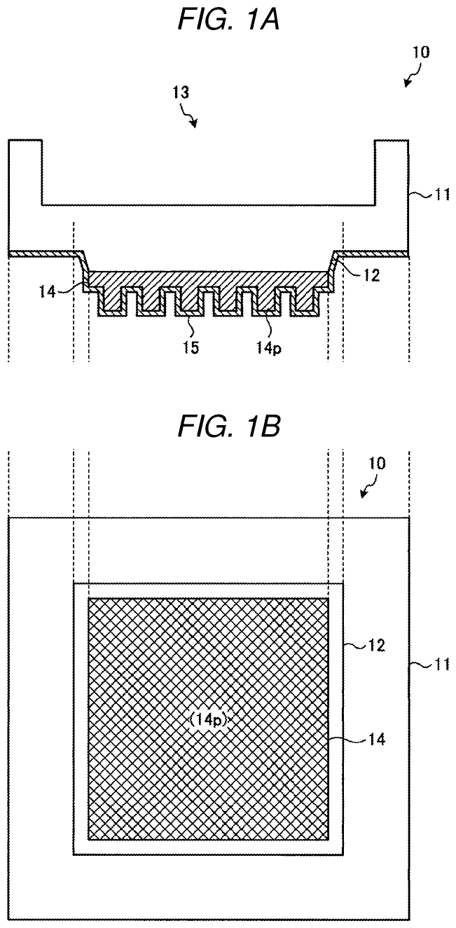

FIGS. 1A and 1B illustrate a structure of an imprint template 10 according to an embodiment. FIG. 1A is a cross-sectional view, and FIG. 1B is a plan view in which an adhesion inhibiting layer 15 is omitted. Hereinafter, the imprint template 10 may be referred to as a template 10.

As illustrated in FIGS. 1A and 1B, the template 10 includes a substrate 11 made of a transparent material such as glass or quartz. The substrate 11 is rectangular, for example. A mesa part 12 is disposed projectingly on one of main surfaces of the substrate 11, as a seating part. The mesa part 12 is disposed, for example, at the center of the substrate 11 and is rectangular. A recessed part is provided to the other main surface of the substrate 11 by removing a part on the other main surface side of the substrate 11.

A resin film 14 is disposed on the top of the mesa part 12 with an adhesive (not separately depicted) therebetween. The adhesive is, for example, a silane coupling agent. That is, the resin film 14 is supported by the mesa part 12 of the substrate 11. The resin film 14 may be made of a transparent resin, such as acrylic resin, epoxy resin, polyamide resin, or polyimide resin.

A recess and projection pattern 14p with fine recesses and projections is disposed on a surface opposite to the mesa part 12 of the resin film 14. The recess and projection pattern 14p may be any pattern having recesses and projections, such as a grooved pattern or a dot pattern.

An adhesion inhibiting layer 15 containing an inorganic element is disposed on a surface along the recesses and projections of the recess and projection pattern 14p. The adhesion inhibiting layer 15 may also be disposed on a side surface of the resin film 14 in addition to the surface of the recess and projection pattern 14p. In addition, the adhesion inhibiting layer 15 may also be disposed on a side surface of the mesa part 12 of the substrate 11. Moreover, the adhesion inhibiting layer 15 may also be disposed on the main surface, on which the mesa part 12 is disposed, of the substrate 11. However, the adhesion inhibiting layer 15 may not be disposed on the side surface of the resin film 14, the side surface of the mesa part 12, and the main surface of the substrate 11 on the condition that the adhesion inhibiting layer 15 covers the surface of the recess and projection pattern 14p.

The inorganic element contained in the adhesion inhibiting layer 15 may be silicon (Si), aluminum (Al), or zirconium (Zr), for example. The adhesion inhibiting layer 15 may be made of at least one oxide of either one of these elements. In one example, the adhesion inhibiting layer 15 is made of at least one of Sio₂, Al₂O₃, and ZrO₂. However, the adhesion inhibiting layer 15 may be made of other material. In this case, the material of the adhesion inhibiting layer 15 is preferably a transparent or approximately transparent material.

The adhesion inhibiting layer 15 has a thickness of 10 nm or less, for example. The thickness of the adhesion inhibiting layer 15 is preferably 1 nm or greater and 10 nm or less.

Method for Manufacturing Template

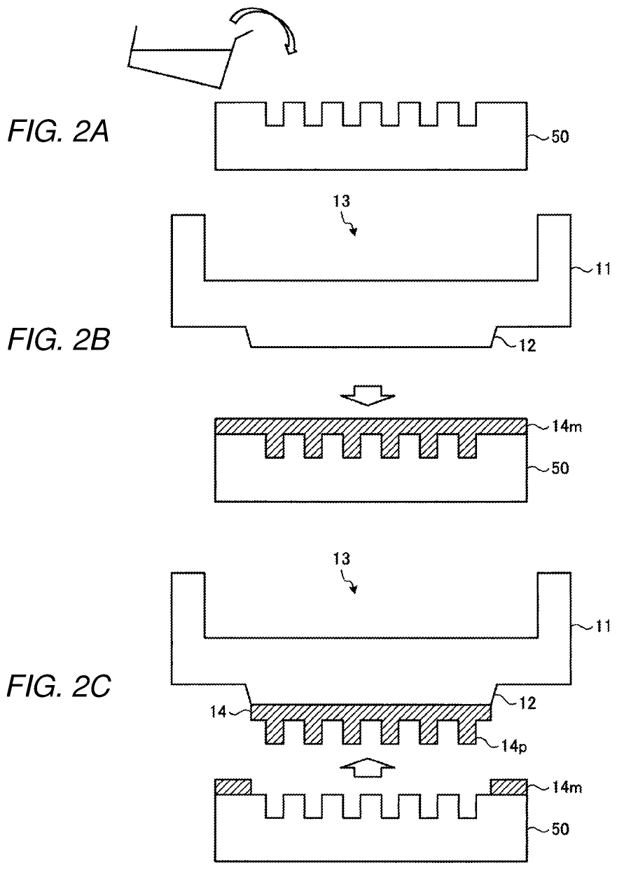

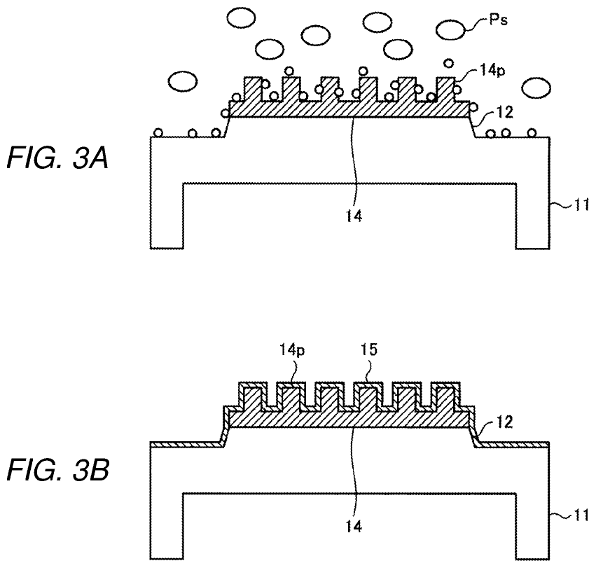

Next, an example of a method for manufacturing the template 10 of the embodiment is described with reference to FIGS. 2A to 2C and FIGS. 3A and 3B. FIGS. 2A to 2C and FIGS. 3A and 3B illustrate a flow of an example of a procedure of a method for manufacturing the template 10 according to the embodiment.

As illustrated in FIG. 2A, the material of the resin film 14 is poured into, for example, a silicon mold 50. The mold 50 forms the resin film 14 with the recess and projection pattern 14p. That is, a pattern reverse to the recess and projection pattern 14p of the resin film 14 is formed in the mold 50.

As illustrated in FIG. 2B, the substrate 11, which has the mesa part 12 and the recessed part 13, is pressed against a resin film 14m that is the material solidified in the mold 50, while the top surface of the mesa part 12 is made to face the resin film 14m. The mesa part 12 and the recessed part 13 are formed by, for example, machining the substrate 11. The top surface of the mesa part 12 has an adhesive thereon, which is not separately illustrated in the drawing.

As illustrated in FIG. 2C, when the substrate 11 is separated from the mold 50, only a part of the resin film 14m on the mold 50 adheres to the mesa part 12 and is peeled off from the mold 50 together with the substrate 11. As a result, the resin film 14 with the recess and projection pattern 14p supported by the mesa part 12 of the substrate 11 is formed.

As illustrated in FIG. 3A, an inorganic substance, an inorganic substance-containing oxide, or other inorganic substance-containing material, is deposited on the surfaces of the resin film 14 and the substrate 11 by, for example, an atomic layer deposition (ALD) method.

Specifically, a precursor Ps containing an inorganic element to be contained in the adhesion inhibiting layer 15 is supplied toward the substrate 11 having the resin film 14. In one example, in order to constitute the adhesion inhibiting layer 15 by using SiO₂, silicon hydride gas, such as monosilane (SiH₄) gas or disilane (Si₂H₆) gas, may be used as the precursor Ps. In another example, in order to constitute the adhesion inhibiting layer 15 by using Al₂O₃, aluminum chloride (AlCl₃) gas or trimethylaluminum (TMA: (CH₃)₃Al) gas may be used as the precursor Ps. In yet another example, in order to constitute the adhesion inhibiting layer 15 by using ZrO₂, zirconium chloride (ZrCl₄) gas or tetrakis(ethylmethylamino)zirconium (TEMAZ: Zr[N(CH₃)(CH₂CH₃)]₄) gas may be used as the precursor Ps. Oxidizing gas, such as O₂ gas, may also be supplied in addition to the gas described above. The precursor Ps is decomposed on the surfaces of the resin film 14 and the substrate 11 by thermal reaction, whereby an inorganic substance, an inorganic substance-containing oxide, or other inorganic substance-containing material, is deposited on the surfaces of the resin film 14 and the substrate 11.

As illustrated in FIG. 3B, the adhesion inhibiting layer 15 with a thickness of, for example, less than or equal to 10 nm is formed as a result of continuing the process of the ALD method for a predetermined time.

As a result, the template 10 of the embodiment is manufactured.

Imprinting Method Using Template

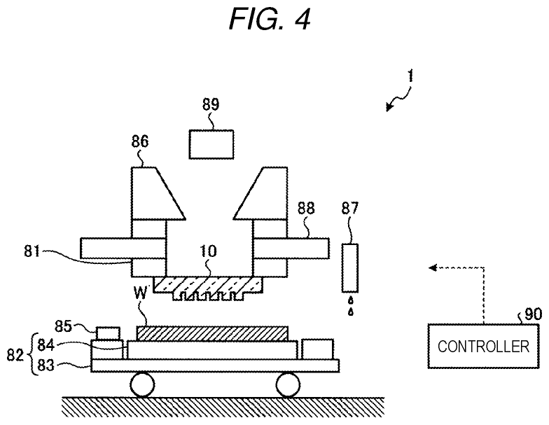

Next, an imprinting method for forming a pattern by using the template 10 is described as an example of using the template 10 of the embodiment. The template 10 is used by installing it in an imprinting apparatus. First, an example of a configuration of an imprinting apparatus 1 is described with reference to FIG. 4. FIG. 4 illustrates an example of a configuration of the imprinting apparatus 1 according to the embodiment.

As illustrated in FIG. 4, the imprinting apparatus 1 includes a template stage 81, a mounting table 82, a reference mark 85, an alignment sensor 86, a liquid dispensing device 87, a stage base 88, a light source 89, and a controller 90. The template 10 is installed in the imprinting apparatus 1.

The mounting table 82 includes a wafer chuck 84 and a main body 83. The wafer chuck 84 secures a wafer W to be used as a substrate, at a predetermined position on the main body 83. The reference mark 85 is provided on the mounting table 82. The reference mark 85 is used for position alignment in loading the wafer W on the mounting table 82.

The mounting table 82 receives the wafer W and moves in a plane or a horizontal plane parallel to the wafer W mounted thereon. The mounting table 82 moves the wafer W under the liquid dispensing device 87 when a resist is to be dispensed on to the wafer W. The mounting table 82 moves the wafer W under the template 10 when a process of transferring to the wafer W is to be performed.

The stage base 88 supports the template 10 by using the template stage 81 and presses the recess and projection pattern 14p of the template 10 against the resist on the wafer W by moving in an up-down direction or a vertical direction. The alignment sensor 86 is provided on the stage base 88. The alignment sensor 86 measures the position of the wafer W and the position of the template 10.

The liquid dispensing device 87 dispenses a resist on to the wafer W by an ink jetting system. The liquid dispensing device 87 includes an ink-jet head that has multiple minute holes for jetting droplets of the resist and dispenses these droplets of the resist on to the wafer W.

The light source 89 emits, for example, ultraviolet rays, and is provided above the stage base 88. The light source 89 emits light from above the template 10 while the template 10 is pressed against the resist.

The controller 90 controls the template stage 81, the mounting table 82, the reference mark 85, the alignment sensor 86, the liquid dispensing device 87, the stage base 88, and the light source 89.

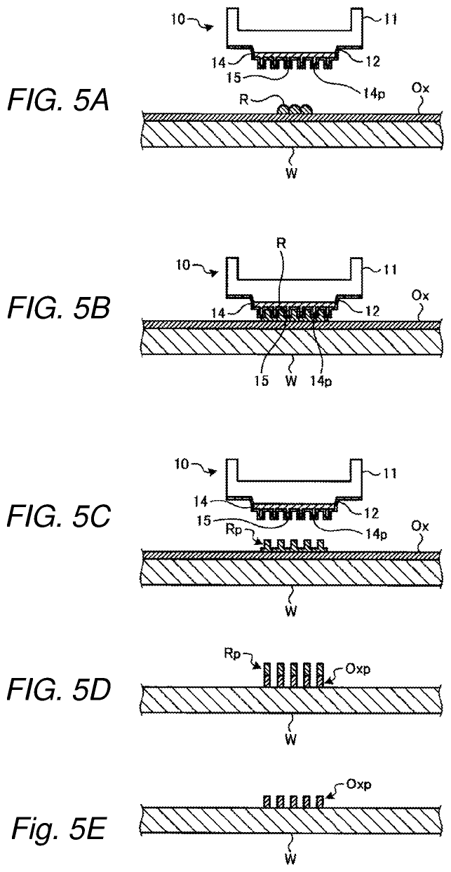

FIGS. 5A to 5E illustrate a flow of an example of a procedure of an imprinting method using the template 10 according to the embodiment. The following imprinting method is executed during performing the method for manufacturing a semiconductor apparatus of the embodiment.

A wafer W that has a processing target film Ox thereon is placed on the mounting table 82, and the mounting table 82 is then moved under the liquid dispensing device 87.

As illustrated in FIG. 5A, droplets of a resist R (to be made into an organic film) are dispensed on to the processing target film Ox from the liquid dispensing device 87. Thereafter, the mounting table 82 is moved under the template 10.

As illustrated in FIG. 5B, the recess and projection pattern 14p of the template 10 is pressed against the resist R in accordance with downward movement of the template stage 81 while the template 10 is aligned with the resist R by measuring the position of the template 10 by the alignment sensor 86.

At this time, a force is applied to the recessed part 13 of the substrate 11 of the template 10 to bring a center part of the template 10, that is, a center part of the recess and projection pattern 14p, into first contact with the resist R. Then, the area of the recess and projection pattern 14p in contact with the resist R is made to spread to an outer circumferential part of the recess and projection pattern 14p. This prevents gas in the atmosphere in the imprinting apparatus 1 from being enclosed in the resist R, thereby preventing generation of bubbles.

Moreover, the resin film 14, which is supported by the mesa part 12 provided at the top of the substrate 11, prevents the body of the substrate 11 from being in contact with the wafer W. That is, in a case of using a resin film that is formed on a flat substrate without the mesa part 12, there may be a risk that the body of the substrate comes too close to the wafer W, resulting in contact with the wafer W. The mesa part 12 prevents such interference between the substrate 11 and the wafer W.

While spreading from the center part to the outer circumferential part of the recess and projection pattern 14p, the resist R also spreads in the recesses of the recess and projection pattern 14p. As a result, the resist R closely adheres to both of the recesses and the projections of the recess and projection pattern 14p.

Then, while the template 10 is pressed against the resist R, the resist R is irradiated with light from the light source 89 of the imprinting apparatus 1 to be cured.

As illustrated in FIG. 5C, the template 10 is separated from the resist R. As a result, the recess and projection pattern 14p is transferred on the processing target film Ox of the wafer W, and a resist pattern Rp is formed.

As illustrated in FIG. 5D, the processing target film Ox is processed by using a mask of the resist pattern Rp, which is formed by transferring the recess and projection pattern 14p. This provides a pattern Oxp of the processing target film Ox.

As illustrated in FIG. 5E, the resist pattern Rp is peeled off by asking or other method, whereby the wafer W on which only the pattern Oxp of the processing target film Ox is formed is obtained.

Then, the method for forming the pattern of the embodiment is finished. In the subsequent stage, the process, as described above, is repeated for forming multiple patterns of the processing target films on the wafer W, whereby a semiconductor device is manufactured.

Although the resist R is dispensed as multiple droplets in the imprinting apparatus 1 of the example embodiment, in other examples, the resist R may be applied to the entire surface of the wafer W by a spin coating method.

### Comparative Examples

Next, comparative examples 1 and 2 are described.

A template with a recess and projection pattern that is directly formed on a mesa part of a glass or quartz substrate has been used. Such a template is exemplified as a comparative example 1. Normally, a template is an article of consumption because the template is abraded by repeated use. For that reason, the cost of the template causes increase in the cost of manufacturing a semiconductor device.

In consideration of this, it may be possible to use resin, such as acrylic resin, for forming a recess and projection pattern of a template. A template having such a recess and projection pattern is exemplified as a comparative example 2. An acrylic resin film is relatively inexpensive, and a relatively expensive substrate may be repeatedly used by replacing only the resin film when the recess and projection pattern is abraded.

However, the resist film is a material relatively similar to a resist of an organic film, and the resist adheres to the recess and projection pattern of the resin film each time the template of the comparative example 2 is used in the imprinting process. This causes widening of the projections of the recess and projection pattern and narrowing of projections formed on the resist. For that reason, it is necessary to replace the resin film at an early time so that the widths of the narrowed projections on the resist will not exceed a specification value, by setting a short service lifetime of the resin film.

The template 10 of the embodiment has the adhesion inhibiting layer 15 that is disposed on the surface of the recess and projection pattern 14p. The adhesion inhibiting layer 15 includes an inorganic element and is made of a material different from that of the resist, thereby inhibiting the resist from adhering to the recess and projection pattern 14p.

The template 10 of the embodiment inhibits the resist from adhering to the recess and projection pattern 14p, due to the adhesion inhibiting layer 15. This prevents widening of the projections of the recess and projection pattern 14p and increases the service lifetime of the resin film 14. For that reason, the cost of the template 10 is reduced, resulting in decrease in the cost of manufacturing a semiconductor device.

Although the adhesion inhibiting layer 15 is formed by the ALD method in the foregoing embodiment, the method of forming the adhesion inhibiting layer 15 is not limited thereto. For example, a chemical vapor deposition (CVD) method may be used instead of the ALD method. The CVD method may also use a gas similar to that used in the ALD method, for forming the adhesion inhibiting layer 15.

Although the adhesion inhibiting layer 15 is formed on the entire surfaces of the resin film 14 and the substrate 11 by supplying the precursor Ps toward the substrate 11, to which the resin film 14 adheres, in the foregoing embodiment, the structure is not limited thereto. A template that does not have the adhesion inhibiting layer 15 at least a part of the side surface of the resin film 14, the side surface of the mesa part 12, and the main surface of the substrate 11 may be manufactured by supplying the precursor Ps while the side surface of the resin film 14, the side surface of the mesa part 12, and the main surface on the mesa part 12 side of the substrate 11 are partially or entirely covered with a mask.

Modification

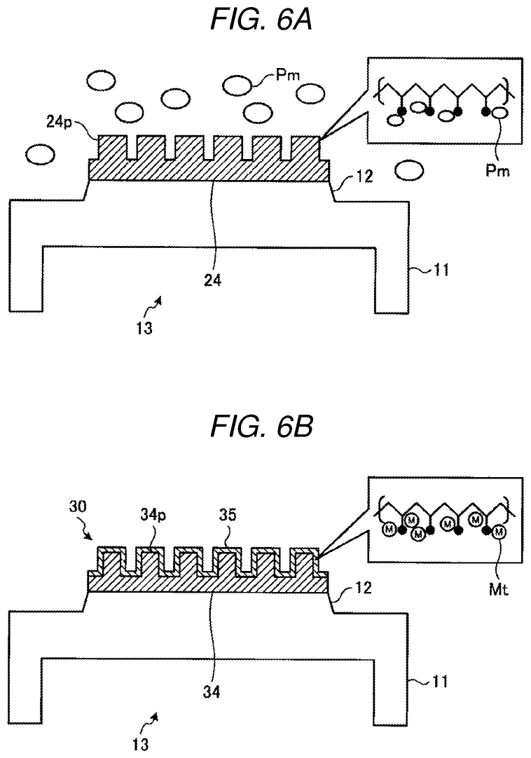

Next, a template 30 of a modification example of the embodiment is described with reference to FIGS. 6A and 6B. The template 30 of the modification example differs from that of the foregoing embodiment in the method of forming an adhesion inhibiting layer 35.

FIGS. 6A and 6B illustrate a flow of an example of a procedure of a method for manufacturing the template 30 of the modification example according to the embodiment.

As illustrated in FIG. 6A, a member with a resin film 24 that is disposed on a substrate 11 having a mesa part 12 and a recessed part 13 is prepared. The resin film 24 has a recess and projection pattern 24p. This member may be obtained by a process similar to that described in FIGS. 2A to 2C in the foregoing embodiment. However, the resin film is preferably formed so as to have an entire film thickness and a width of the projection that are equal to the corresponding dimensions of the resin film 14 formed with the adhesion inhibiting layer 15. That is, the entire film thickness and the width of the projection of the resin film 24 are greater than the corresponding dimensions of only the resin film 14.

Then, a metal-containing precursor Pm is supplied to the substrate 11 with the resin film 24 thereon, and the surface of the resin film 24 is thus metalized. The metalizing of the resin film 24 means that a specific type of metal is impregnated into the resin film 24. Specifically, the resin film 24 is exposed to the precursor Pm and is oxidized, whereby a metallic compound is deposited in the resin film 24. A precursor containing aluminum or zirconium, as described in the foregoing embodiment, may be used as the precursor Pm. The metalizing may also be called a sequential infiltration synthesis (SIS) method, hereinafter.

The resin film 24 is made of a transparent resin, such as acrylic resin, epoxy resin, polyamide resin, or polyimide resin, as in the foregoing embodiment. These transparent resins contain a carbonyl group (>C═O) in their structures. The precursor Pm is covalently bonded to the carbonyl group, and the metal of the precursor Pm is deposited as a metallic compound by the subsequent oxidation treatment. This mechanism differs from that of the ALD method in which a precursor adsorbs to the surface of a target object to form a single deposition layer.

The black circle marks in FIGS. 6A and 6B represent a carbonyl group at a metal coordination point of a transparent resin, such as acrylic resin.

As illustrated in FIG. 6B, a resin film 34 is formed by performing the oxidation treatment after the resin film 24 is exposed to the precursor Pm for a predetermined time. The resin film 34 includes an adhesion inhibiting layer 35 that is formed on the surface of a recess and projection pattern 34p. The adhesion inhibiting layer 35 includes a polymer component of the resin film 24 and a metallic element. More specifically, the adhesion inhibiting layer 35 includes a metallic compound Mt that is impregnated into the resin film 24. The thickness of the adhesion inhibiting layer 35 depends on the depth of the precursor Pm impregnated into the resin film 24. The depth of the impregnated precursor Pm is controlled by adjusting a time of exposing the resin film 24 to the precursor Pm, temperature, concentration of the precursor Pm, and other factors.

The adhesion inhibiting layer 35 has a concentration gradient in which the concentration of metal gradually decreases from the surface to the inside of the adhesion inhibiting layer 35. That is, the concentration of metal is high at the surface of the adhesion inhibiting layer 35, whereas the concentration of metal is low at the inside of the adhesion inhibiting layer 35. The metal may be impregnated into the resin film 34 at a region deeper than the adhesion inhibiting layer 35. In this case, a region having a concentration of metal of a predetermined value or higher is defined as the adhesion inhibiting layer 35.

The adhesion inhibiting layer 35 that is formed by the above-described method is not formed on the side surface of the mesa part 12 and the main surface on the mesa part 12 side of the substrate 11.

The dimensions of each part of the resin film 34 subjected to metalizing are made approximately equal to the dimensions of each corresponding part of the resin film 14 of the embodiment by adjusting the dimensions of each part of the resin film 24 prior to metalizing, as described above. The dimensions of each part of the set of the resin film 34 and the adhesion inhibiting layer 35 subjected to metalizing are slightly greater than those of each corresponding part of the resin film 24 before the metalizing is performed, due to the impregnated metallic compound Mt. For that reason, it is more preferable to adjust the dimensions of each part of the resin film 24 prior to metalizing, in consideration of this point.

The template 30 of the modification example provides effects similar to those of the template 10 of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint template, comprising:
a substrate;
a resin film on the substrate and having an imprint pattern therein; and
a resist-repellant layer provided on a surface of the imprint pattern, the resist-repellant layer containing an inorganic element.

2. The imprint template according to claim 1, wherein a thickness of the resist-repellant layer is equal to or less than 10 nm.

3. The imprint template according to claim 2, wherein the thickness of the resist-repellant layer is equal to or greater than 1 nm.

4. The imprint template according to claim 1, wherein the inorganic element is a metallic element.

5. The imprint template according to claim 1, wherein the inorganic element is one of silicon, aluminum, and zirconium.

6. The imprint template according to claim 1, wherein the resist-repellant layer includes a polymer component which is the same as the resin film and the inorganic element is a metallic element.

7. The imprint template according to claim 6, wherein a concentration of the metallic element gradually decreases from an outer surface of the resist-repellant layer toward the resin film.

8. The imprint template according to claim 1, wherein the resist-repellant layer comprises an oxide material.

9. The imprint template according to claim 8, wherein the oxide material is SiO₂, Al₂O₃, or ZrO₂.

10. The imprint template according to claim 1, wherein the resist-repellant layer is on a front surface and side surfaces of the imprint pattern.

11. A method for manufacturing an imprint template, the method comprising:
pressing a substrate against a resin film that is been solidified in a mold having a pattern therein,
transferring the solidified resin film having an imprint pattern formed therein corresponding to the pattern to the substrate; and
forming a resist-repellant layer on a surface of the imprint pattern, the resist-repellant layer containing an inorganic element.

12. The method according to claim 11, wherein a thickness of the resist-repellant layer is equal to or greater than 1 nm and equal to or less than 10 nm.

13. The method according to claim 11, wherein the inorganic element is a metallic element.

14. The method according to claim 11, wherein the inorganic element is one of silicon, aluminum, and zirconium.

15. The method according to claim 11, wherein the resist-repellant layer comprises a polymer component that is the same as the resin film.

16. The method according to claim 11, wherein the resist-repellant layer comprises an oxide material.

17. The method according to claim 16, wherein the oxide material is SiO₂, Al₂O₃, or ZrO₂.

18. The imprint template according to claim 11, wherein the resist-repellant layer is formed on a front surface and side surfaces of the imprint pattern.

19. The imprint template according to claim 11, wherein the resist-repellant layer is formed using an atomic layer deposition method.

20. The imprint template according to claim 11, wherein the resist-repellant layer is formed using a sequential infiltration synthesis method.
